(19) United States
(12) Patent Application Publication
(10) Pub. No.: US 2007/0158737 A1
(43) Pub. Date: Jul. 12, 2007

(54) Semiconductor device with mask read-only memory and method of fabricating the same

(75) Inventors: Seung-Jin Yang, Seoul (KR); Jeong-Uk Han, Suwon-si (KR)

Correspondence Address: F. Chau & Associates, LLC, 130 Woodbury Road, Woodbury, NY, 11797, US

(73) Assignee: Samsung Electronics Co., Ltd.

(21) Appl. No.: 11/646,165

(22) Filed: Dec. 27, 2006

(30) Foreign Application Priority Data
Jan. 6, 2006 (KR) 2006-01891

(51) Int. Cl. H01L 29/788; H01L 21/336

(52) U.S. Cl. 257/315; 257/316; 438/266; 438/593

(57) ABSTRACT

A mask read only memory (ROM) device includes a plurality of isolation patterns disposed at predetermined regions of a semiconductor substrate to define a plurality of active regions. The semiconductor substrate includes a mask ROM region where a plurality of on cells and a plurality of off-cells are disposed. The mask ROM further includes a plurality of gate lines disposed over the active regions, and which cross over the isolation patterns, a plurality of gate insulating layers interposed between the gate lines and the active regions and a floating conductive pattern and a inter-gate dielectric pattern located between the gate line and the gate insulating layer of the off-cell.

### CROSS-REFERENCE TO RELATED APPLICATIONS

This U.S. non-provisional patent application claims priority under 35 U.S.C. § 119 of Korean Patent Application No. 2006-01891 filed on Jan. 6, 2006, the disclosure of which is hereby incorporated by reference herein in its entirety.

### BACKGROUND

1. Technical Field

The present disclosure relates to semiconductor devices and method of fabricating the same and in particular relates to a semiconductor device with a mask read-only memory (mask ROM) and to a method of fabricating the same.

2. Discussion of the Related Art

Due to the popularization of portable electronic apparatuses such as, for example, mobile phones, personal digital assistants (PDA), digital cameras, camcorders, gaming machines, there has been an increasing demand for embedded-memory-and-logic (EML) semiconductor device equipped with memories and logic circuits on a single chip.

FIG. 1 shows a chip layout pattern of an EML semiconductor device as an example.

Referring to FIG. 1, the EML semiconductor device 10 may be fabricated to include a logic circuit area 11 for conducting inherent functions, a nonvolatile memory area 12 for storing data in nonvolatile condition, and a mask ROM area 13 for storing predetermined program codes. In addition, the EML semiconductor device 10 may further include a volatile memory area 14 for temporarily storing data. According to an example of the conventional art, an electrically erasable and programmable ROM is disposed in the nonvolatile memory area 12, and a static random access memory (static RAM) is disposed in the volatile memory area 14. Moreover, in the mask ROM area, mask ROM cells are located in correspondence with the program codes.

The mask ROM cells are differentiated into on-transistors and off-transistors in accordance with threshold voltages thereof. To set those threshold voltages, a conventional method for fabrication is typically used, as shown in FIG. 2. The conventional method includes a step of forming an impurity region 70 for electrically connecting source/drain regions 40 to each other in a channel region of the on-transistor.

For example, the forming of the impurity regions 70 is carried out through a step of injecting ionic impurities into the channel region of the on-transistor by using a photoresist pattern 50 as an ion implantation mask (refer to 60 in FIG. 2). In step 60, as a gate electrode 30 is located over the channel region, implantation energy should be high so as to make the ionic impurities reach the channel region. However, as the high implantation energy may result in an increased diffusion length of the impurities, the ionic impurities injected with high energy may thus be diffused to an adjacent transistor during the subsequent processing step. Consequently, the above-mentioned inadvertent diffusion of impurities may result in a threshold voltage change for the adjacent transistor, which in turn may cause an abnormal operation for the device.

Furthermore, as the impurity injection step may require photolithography and high-energy ion implantation processes whose costs are typically high, the use of a conventional method of fabricating the EML chip may likewise result in high manufacturing costs. Additionally, the high-energy ion implantation process of the above-mentioned conventional method may also be inconvenient to use because it may require preparing a thick photoresist pattern that causes various technical difficulties.

### SUMMARY OF THE INVENTION

Embodiments of the present invention are directed to a method of fabricating a mask ROM, controlling threshold voltages of mask ROM transistors without an ion implantation step using a photoresist pattern as an ion implantation mask.

Embodiments of the present invention are also directed to a method of fabricating an EML semiconductor device with a mask ROM in low cost.

Embodiments of the present invention are further directed to a mask ROM device capable of reducing a change of threshold voltages caused by a diffusion of impurities.

Embodiments of the present invention are still further directed to an EML semiconductor device including a mask ROM device in which a threshold voltage can be prevented from changing owing to a diffusion of impurities.

In accordance with an embodiment of the present invention a mask read only memory (ROM) device is provided. This mask ROM device includes a plurality of isolation patterns disposed at predetermined regions of a semiconductor substrate to define a plurality of active regions. The semiconductor substrate includes a mask ROM region where a plurality of on cells and a plurality of off-cells are disposed. The mask ROM further includes a plurality of gate lines disposed over the active regions and which cross over the isolation patterns, a plurality of gate insulating layers interposed between the gate lines and the active regions and a floating conductive pattern and a inter-gate dielectric pattern located between the gate line and the gate insulating layer of the off-cell.

According to an embodiment, the gate insulating layer may be thicker under the gate line of the off-cell than under the gate line of the on-cell. For instance, the gate insulating layer may be formed to a thickness of about 10 Å through about 50 Å under the gate line of the on-cell and to a thickness of about 50 Å through about 400 Å under the gate line of the off-cell.

Additionally, the floating conductive pattern is electrically isolated from the gate line through the inter-gate dielectric pattern. The inter-gate dielectric pattern may be formed of at least one high-k dielectric layer material selected from the group consisting of metallic oxides, a silicon oxide layer, and a silicon nitride layer.

According to an embodiment, in the off-cell, the gate line not greater than the floating conductive pattern in width.

In accordance with an embodiment of the present invention, a semiconductor device having a mask read only memory (ROM) is provided. The semiconductor device includes a plurality of isolation patterns disposed at predetermined regions of a semiconductor substrate to define a plurality of active regions. The semiconductor substrate includes a nonvolatile memory area and a mask ROM region where a plurality of on cells and a plurality of off-cells are disposed. The semiconductor device further includes a plurality of gate lines disposed over the active regions and which cross over the isolation patterns and a plurality of gate insulating layers interposed between the gate lines and the active regions and a first floating conductive pattern and an inter-gate dielectric pattern that are located between the gate line and the gate insulating layer of the off cell; and a second floating conductive pattern and a inter-gate dielectric pattern located between the gate line and the gate insulating layer of the nonvolatile memory area. In the on-cell, the gate line directly contacts the gate insulating layer.

According to an embodiment, the gate insulating layer may be thicker under the gate line of the off-cell than under the gate line of the on-cell. Further, the gate insulating layer under the gate line of the off-cell includes a part having the same thickness as the gate insulating layer under the gate line of the nonvolatile memory area. For example, the gate insulating layer may be formed to a thickness of about 10 Å through about 50 Å under the gate line of the on-cell and to a thickness of about 50 Å through about 400 Å under the gate lines of the off-cell and the nonvolatile memory area.

Additionally, the first floating conductive pattern may be the same as the second floating conductive pattern with regard to kind of material and to thickness. The first inter-gate dielectric pattern may be the same as the second inter-gate dielectric pattern with regard to kind of material and to thickness.

According to an embodiment, the first and second floating conductive patterns are electrically isolated from the gate lines through the first and second inter-gate dielectric patterns. At least one of the first and second inter-gate dielectric patterns may be formed of at least one high-k dielectric layer material selected from the group consisting of metallic oxides, a silicon oxide layer, and a silicon nitride layer.

According to an embodiment, the gate line of the off-cell is not greater than the first floating conductive pattern in width, and the gate-line of the nonvolatile memory area is equal to the second floating conductive pattern in width.

In addition, the gate insulating layer of the nonvolatile memory area may be comprised of a tunnel region, in which the gate insulating layer of the tunnel region is thinner than the adjacent region. The semiconductor device may further include silicon oxide patterns disposed between the first floating conductive pattern and the first inter-gate dielectric pattern and between the second floating conductive pattern and the second inter-gate dielectric pattern, defining top edges of the first and second floating conductive patterns in acute angles.

In accordance with an embodiment of the present invention, a mask read only memory (ROM) device is provided. The mask ROM device includes a semiconductor substrate including a mask ROM cell array including a plurality of on-transistors and a plurality of off-transistors, a plurality of first active regions used for drain and channel regions of the on and off-transistors, extending one direction in predetermined areas of the semiconductor substrate, a plurality of second active regions used for source regions of the on and off-transistors, connecting the first active regions with each other and extending the other direction in predetermined areas of the semiconductor substrate. The mask ROM further includes a plurality of gate lines used for gate lines of the on and off-transistors, which cross over the first active regions, a plurality of bit lines which cross over the gate lines to connect the drain regions with each other, and a floating conductive pattern and a inter-gate dielectric pattern disposed between the gate line of the off-transistor and the first active region.

In accordance with an embodiment of the present invention, a method of fabricating a mask read only memory (ROM) device is provided. This method includes forming a plurality of isolation patterns in a semiconductor substrate to define a plurality of active regions. The semiconductor substrate has a mask ROM region where a plurality of on cells and a plurality of off-cells are disposed. The method further includes forming a first gate insulation pattern and a floating conductive pattern on the active region of the off-cell while exposing the active region of the on-cell. Thereafter, a second gate insulating layer is formed on the exposed active region of the on-cell, and a plurality of gate lines are formed over the second gate insulating layer of the on-cell and the first floating conductive pattern of the off-cell.

According to an embodiment, the second gate insulating layer may be thinner than the first gate insulation pattern. For instance, the first gate insulation pattern may be formed to a thickness of about 50 Å through about 400 Å and the second gate insulating layer may be formed to a thickness of about 10 Å through about 50 Å.

The forming of the first gate insulation and floating conductive patterns includes forming a first gate insulating layer on the active region, forming a first conductive layer on the resultant structure including the first gate insulating layer and patterning the first conductive and gate insulating layers to expose the top of the active region of the on-cell.

According to an embodiment, the method may further include forming an inter-gate dielectric layer on the first conductive layer. During this, the inter-gate dielectric layer is patterned along with the first conductive and gate insulating layers and transformed into an inter-gate dielectric pattern disposed between the first floating conductive pattern and the gate line.

According to another embodiment, the method may further include forming a silicon oxide pattern partially on the first conductive layer. During this, the silicon oxide pattern is used as an etching mask for defining the first floating conductive and gate insulation patterns while patterning the first conductive and gate insulating layers. The method may be further include: before forming the second gate insulating layer, forming a tunnel insulating layer to cover the active region around the first floating conductive pattern, forming an inter-gate dielectric layer to cover the resultant structure including the tunnel insulating layer and removing the inter-gate dielectric layer and the tunnel insulating layer from a region of the mask ROM.

According to an embodiment, the gate line is not greater than the first floating conductive pattern in width.

This method includes forming a plurality of isolation patterns in a semiconductor substrate to define a plurality of active regions. The semiconductor substrate including a nonvolatile memory area and a mask ROM region where a plurality of on cells and a plurality of off-cells are disposed. The method further includes forming a first gate insulation pattern and a floating conductive pattern on the nonvolatile memory area and the active region of the off-cell, forming a second gate insulating layer on the active region around the first floating conductive pattern and forming a plurality of gate lines on the second gate insulating layer of the on-cell, the first floating conductive pattern of the off-cell, and in the nonvolatile memory area. The gate lines cross over the active regions.

In accordance with an embodiment of the invention, a method of fabricating a mask read only memory (ROM) device is provided. The method includes forming a plurality of isolation layers in predetermined regions of a semiconductor substrate including a plurality of on cells and a plurality of off-cells to define a plurality of first active regions and a plurality of second active regions. The first active regions are disposed along one direction and the second active regions are disposed along the other direction to connect the first active regions with each other. The method further includes forming first gate insulation pattern and a floating conductive pattern on the active region of the off-cell, forming a second gate insulating layer on the first and second active regions around the first floating conductive pattern, forming a gate line crossing over the first active regions and disposed over the second gate insulating layer of the on-cell and the first floating conductive pattern of the off-cell, and forming drain and source regions in the first and second active regions by using the gate lines as an ion implantation mask.

According to an embodiment, the first and second active regions are formed to intersect each other, and the isolation patterns are formed enclosed by the first and second active regions. Here, the isolation patterns are arranged along a longitudinal axis parallel with the first active regions.

Additionally, a couple of the gate lines are formed on each of the isolation patterns. The couple of the gate lines are arranged in parallel with the first active regions.

### BRIEF DESCRIPTION OF THE DRAWINGS

Exemplary embodiments of the present invention can be understood in more detail from the following description taken in conjunction with the accompanying drawings, in which:

FIG. 1 shows a chip layout pattern of an EML semiconductor device as an example;

FIG. 2 is a sectional diagram showing a conventional method of fabricating a mask ROM;

FIG. 3 is a circuit diagram illustrating a cell array of a mask Rom according to an embodiment of the present invention;

FIGS. 4A through 8A are plane diagrams illustrating a method of fabricating a mask ROM in accordance with an embodiment of the present invention;

FIGS. 4B through 8B are sectional diagrams illustrating a method of fabricating a mask ROM in accordance with an embodiment of the present invention;

FIGS. 9A through 13A are plane diagrams illustrating a method of fabricating a mask ROM in accordance with an embodiment of the present invention; and

FIGS. 9B through 13B are sectional diagrams illustrating a method of fabricating a mask ROM in accordance with an embodiment of the present invention.

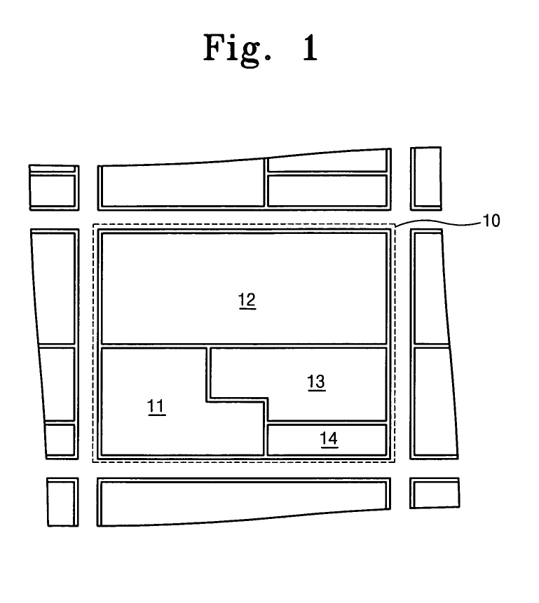

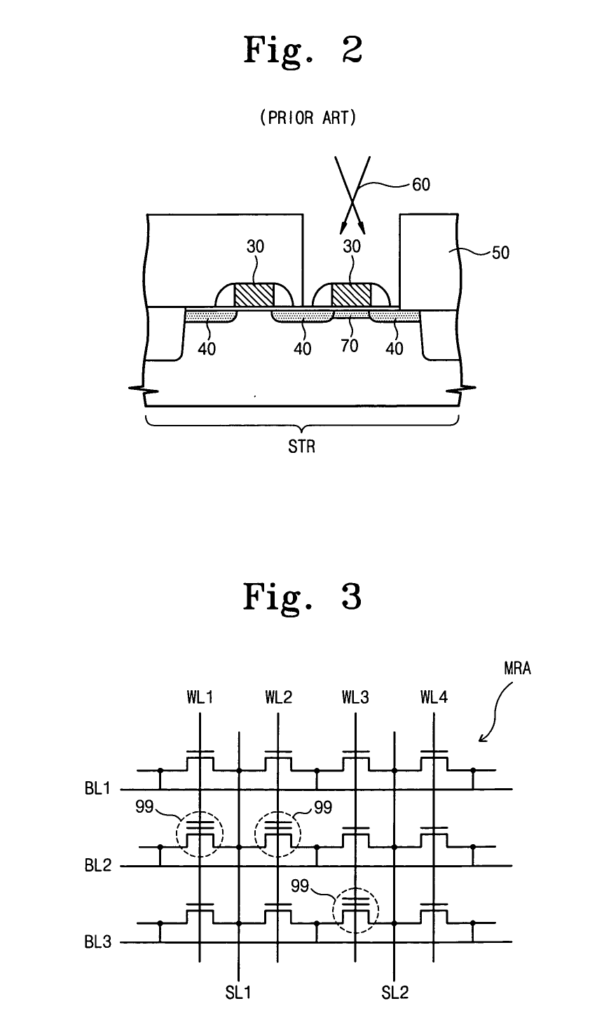

### DETAILED DESCRIPTION OF PREFERRED EMBODIMENTS

Preferred embodiments of the present invention will be described below in more detail with reference to the accompanying drawings. The present invention may, however, be embodied in different forms and should not be constructed as limited to the preferred embodiments set forth herein.

In the figures, the dimensions of layers and regions are exaggerated for clarity of illustration. It will also be understood that when a layer (or layer) is referred to as being ‘on’ another layer or substrate, it can be directly on the other layer or substrate, or intervening layers may also be present. Further, it will be understood that when a layer is referred to as being ‘under’ another layer, it can be directly under, and one or more intervening layers may also be present. In addition, it will also be understood that when a layer is referred to as being ‘between’ two layers, it can be the only layer between the two layers, or one or more intervening layers may also be present. Like reference numerals refer to like elements throughout.

The embodiments of the present invention may be applicable to not only the EML semiconductor devices but also to, for example, a mask ROM device or a semiconductor device having a mask ROM and nonvolatile memory.

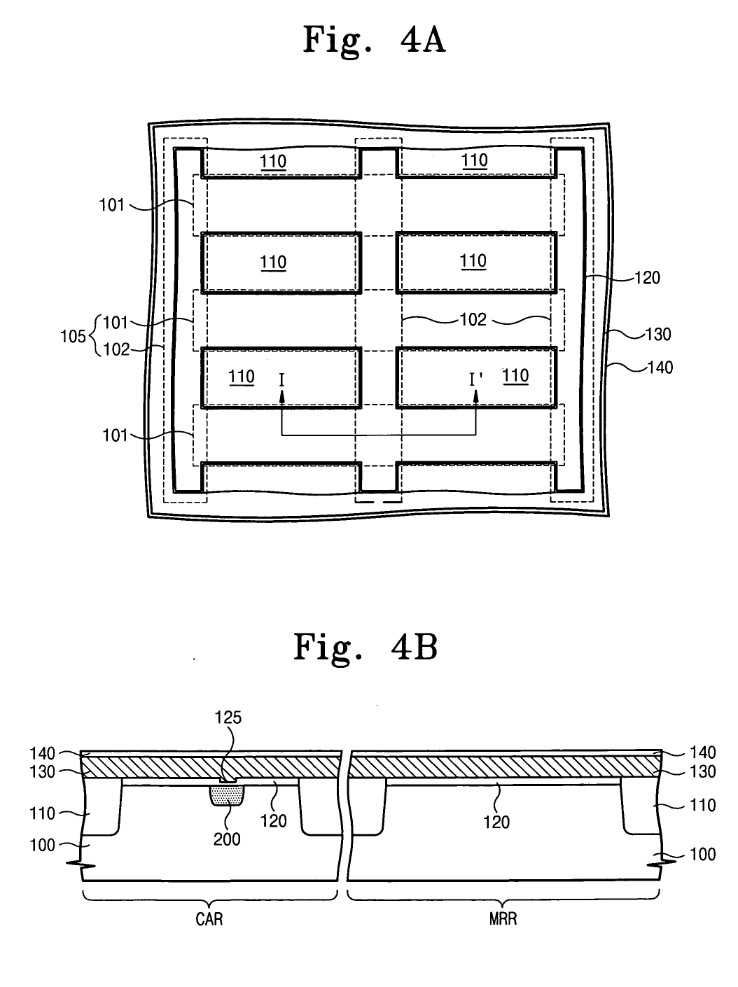

FIG. 3 is a circuit diagram illustrating a cell array of a mask Rom according to an embodiment of the invention.

Referring to FIG. 3, the mask ROM cell array (MRA) of an embodiment of the present invention comprises cell transistors arranged in second dimensions. Gate and drain electrodes of the cell transistors are respectively connected through a plurality of word lines WL1˜WL4 and a plurality of bit lines BL1˜BL3, which cross over each other. To apply operation voltages independently, all of word lines WL1˜WL4 and all of bit lines BL1˜BL4 are separated from each other. Source electrodes of the cell transistors are connected by source lines SL1 and SL2 that are parallel with the word lines. The source lines, SL1 and SL2, may be electrically connected to have the same potential.

The cell transistors, which constitute the mask ROM cell array MRA, are differentiated into on-transistors and off-transistors 99 according to threshold voltages thereof. The on-transistors and off-transistors 99 are 2-dimensionally arranged in correspondence with program codes provided by a system developer.

According to the current embodiment of present invention, a gate electrode of the off-transistor 99 comprises a floating conductive pattern disposed between the word line WL and a semiconductor substrate. The floating conductive pattern is electrically isolated from the word line WL. Namely, the gate electrode of the off-transistor 99 is similar to a gate structure of a floating-gate nonvolatile memory device. Due to this structural addition of the floating conductive pattern, the channel region of the off-transistor is not inverted even by a reading voltage, which is applied on the wordline in a reading step. As a result, the off-transistor can be sensed as an off-state.

Further, a gate insulating layer interposed between the gate electrode and the semiconductor substrate may be thicker in the off-transistor than in the on-transistor. This differential thickness of gate insulating layer between the on and off-transistors may also contribute to sensing the off-transistor as an off-state. Hereinbelow, the details regarding the features relevant to the presence of the floating conductive pattern and the thickness difference will be set forth in more detail. Due to the similarity with the floating-gate gate structure of nonvolatile memory device (e.g. flash memory), the mask ROM according to embodiments of the present invention may be fabricated by means of a method for manufacturing a normal floating-gate nonvolatile memory. Therefore, for an EML semiconductor device having the floating-gate nonvolatile memory device and the mask ROM on a single chip, it is possible to minimize the number of processing steps when fabricating the mask ROM.

FIGS. 4A through 8A are plane diagrams illustrating a method of fabricating a mask ROM in accordance with an embodiment of the invention. In addition, FIGS. 4B through 8B are sectional diagrams illustrating a method of fabricating a mask ROM, accompanying with FIGS. 4A through 8A. In FIGS. 4B through 8B, the cell array region CAR depicted at the left side shows a section of cell array in the floating-gate nonvolatile memory, while the mask ROM region MRR depicted at the right side is correspondent with a section taken along line I-I′ of FIGS. 4A through 8B.

First, referring to FIGS. 4A and 4B, isolation patterns 110 are formed in predetermined areas of the semiconductor substrate 100, defining active regions 105. The semiconductor substrate 100 has the mask ROM region MRR including on-cells and off-cells. The on and off-cells are correspondent with regions where the on and off-transistors are disposed, respectively. As will be described later, the off-transistor may be comprised of a floating conductive pattern placed on a gate insulating layer, similar to the gate structure of the floating-gate nonvolatile memory device.

The isolation patterns 110 may be formed by means of shallow trench isolation (STI) or local oxidation of silicon (LOCOS). According to an embodiment of the invention, an active region 105 located in the mask ROM region MRR is formed including first active regions 101 extending along one direction, and second active regions 102 extending along the other direction to connect the first active regions 101. According to this embodiment, the isolation patterns 110 are configured in the shape of islands on a longitudinal axis parallel with the first active regions 101 and the active region 105 being formed in the shape of a net enclosing the isolation patterns 110. In the subsequent process, the first active regions 101 are used for drain and channel regions of the cell transistors, while the second active regions 102 are used for source regions of the cell transistors.

A first gate insulating layer 120 is deposited on the active region 105. The gate insulating layer 120 is preferred to be made of, for example, silicon oxide that is formed by thermal oxidation. But, the gate insulating layer 120 may be formed of, for example, high-k dielectric layers that are formed by means of chemical vapor deposition (CVD) of atomic layer deposition (ALD). For instance, such high-k dielectric layers may include tantalum oxide (Ta₂O₅), aluminum oxide (Al₂O₃), titanium oxide (Ta₂O₅), silicon oxide (SiO₂), silicon nitride (Si₃N₄), hafnium oxide (HfO₂), BST ((Ba,Sr)TiO₃), and lead-zirconium-titanate (PZT). The first gate insulating layer 120 may be formed, for example, to a thickness of about 50 angstroms (Å) through about 400 Å.

Thereafter, a first conductive layer 130 is deposited on the resultant structure including the first gate insulating layer 120. The first conductive layer 130 may be formed of, for example, polycrystalline silicon to a thickness of about 600 Å through about 2000 Å. According to this embodiment, an inter-gate dielectric layer 140 is deposited on the first conductive layer 130. The inter-gate dielectric layer 140 may be formed of, for example, at least one material selected the group consisting of from silicon oxide and silicon nitride. For instance, the inter-gate dielectric layer 140 may be formed of a sequentially stacked silicon oxide, silicon nitride, and silicon oxide layer. The inter-gate dielectric layer 140 may be formed, for example, by means of CVD to a thickness of about 80 Å through about 200 Å.

Meanwhile, the embodiments of the present invention are applicable to, for example, an EML semiconductor memory device including a floating-gate/oxide-layer (FLOTOX) EEPROM (e.g., a kind of the floating-gate nonvolatile memory device). According to this embodiment, before depositing the first conductive layer 130, a tunnel insulating layer 125 is formed on the active region 105 of the cell array region CAR to a thickness smaller than that of the first insulation gate 120. In detail, this operation is carried out including steps of patterning the first gate insulating layer 120 to form a tunnel opening that partially exposes the active region 105 (e.g., the first active region 101), and forming the tunnel insulating layer 125 in the tunnel opening. The tunnel insulating layer 125 may be formed of, for example, at least one material selected from the group consisting of silicon oxide, silicon nitride, and silicon oxynitride by means of thermal oxidation or deposition. In addition, before depositing the tunnel insulating layer 125, a tunnel impurity region 200 may be formed in the active region 105 under the tunnel opening.

Furthermore, this embodiment may also include, before depositing the inter-gate dielectric layer 140, a step of patterning the first conductive layer 130 to form a floating opening that exposes the top of the isolation pattern 110. The floating opening is used to define a gloating gate of the FLOTOX EEPROM.

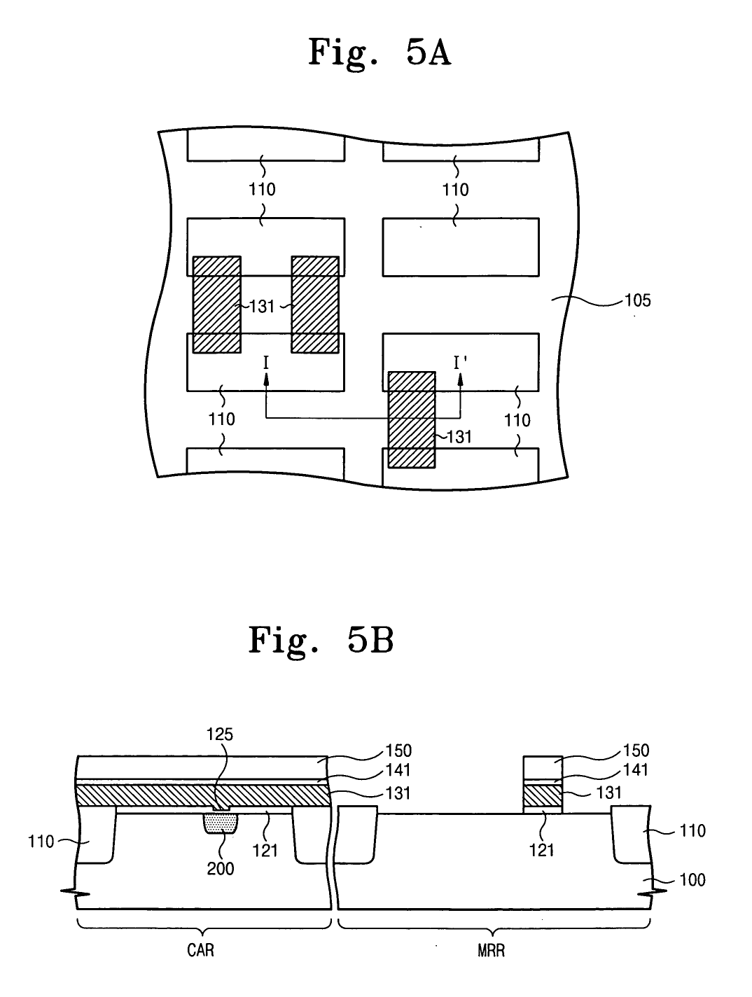

Next, referring to FIGS. 5A and 5B, the inter-gate dielectric layer 140, the first conductive layer 130, and the first gate insulating layer 120 are patterned to form a first gate insulation pattern 121, a first floating conductive pattern 131, a first inter-gate dielectric pattern 141, which are stacked in sequence. This patterning process is carried out including a step of forming a mask pattern 150 on the inter-gate dielectric layer 140 for an etching mask. The mask pattern 150 may be, for example, a photoresist pattern prepared by a photolithography process. During this, the first floating conductive pattern 131 and the first inter-gate dielectric pattern 141, which are formed in the mask ROM region MRR, expose the active region 105 therearound but remain in the cell array region CAR of the floating-gate nonvolatile memory device (e.g., FLOTOX EEPROM or flash memory) without being etched away therefrom.

This patterning operation uses a typical process for the floating-gate nonvolatile memory device, so it can be carried out without an additional processing step. In further detail, the procedure for fabricating the floating-gate nonvolatile memory device is conducted including the step of removing the inter-gate dielectric layer 140, the first conductive layer 130, and the first gate insulating layer 120 from regions except the cell array region CAR where a floating gate pattern will be arranged, thereby exposing the top of the active region 105. By way of this processing step, the first gate insulating layer 121, the first floating conductive pattern 131, and the first inter-gate dielectric pattern 141 may be formed to expose the active region 105 of the mask ROM region MRR without increasing the number of processing steps.

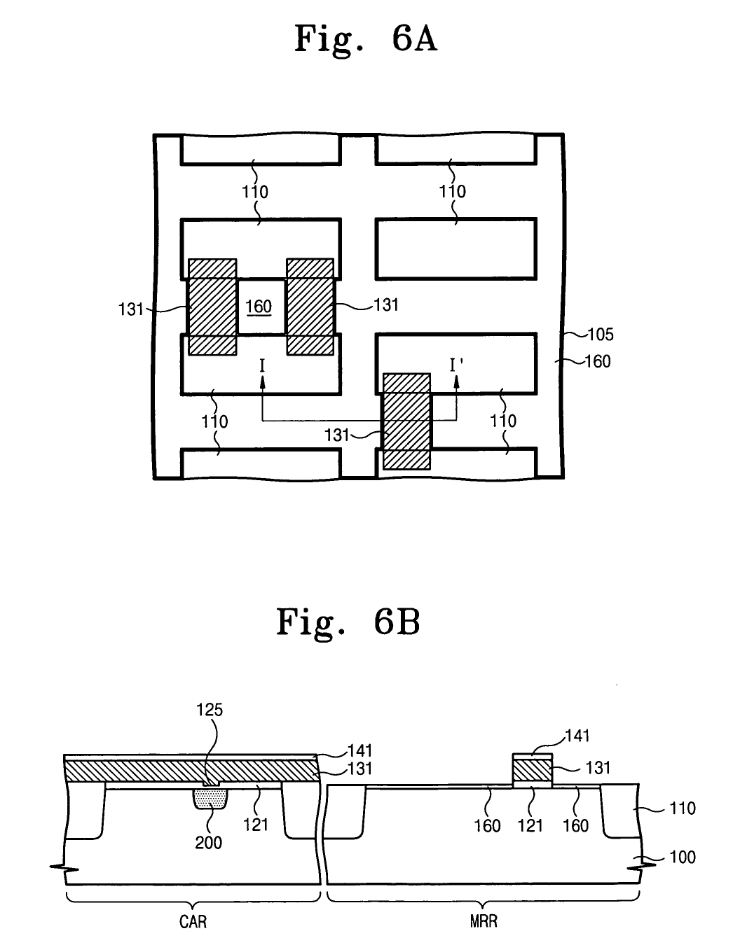

Next, referring to FIGS. 6A and 6B, a second gate insulating layer 160 is deposited on the exposed active region 105. The second gate insulating layer 160 may be formed of, for example, silicon oxide by means of thermal oxidation to a thickness of about 10 Å through about 50 Å. Thus, the second gate insulating layer 160 is formed thinner than the first gate insulating layer 120.

Meanwhile, the second gate insulating layer 160 may be deposited on the top of the first gate insulation pattern 141 and a sidewall of the first floating conductive pattern 131. Thus, it is proper for the inter-gate dielectric layer 140 and the first floating conductive pattern 131 to be formed depending upon characteristics such as for example, additional deposition thickness and the thickness of sidewall oxide layer.

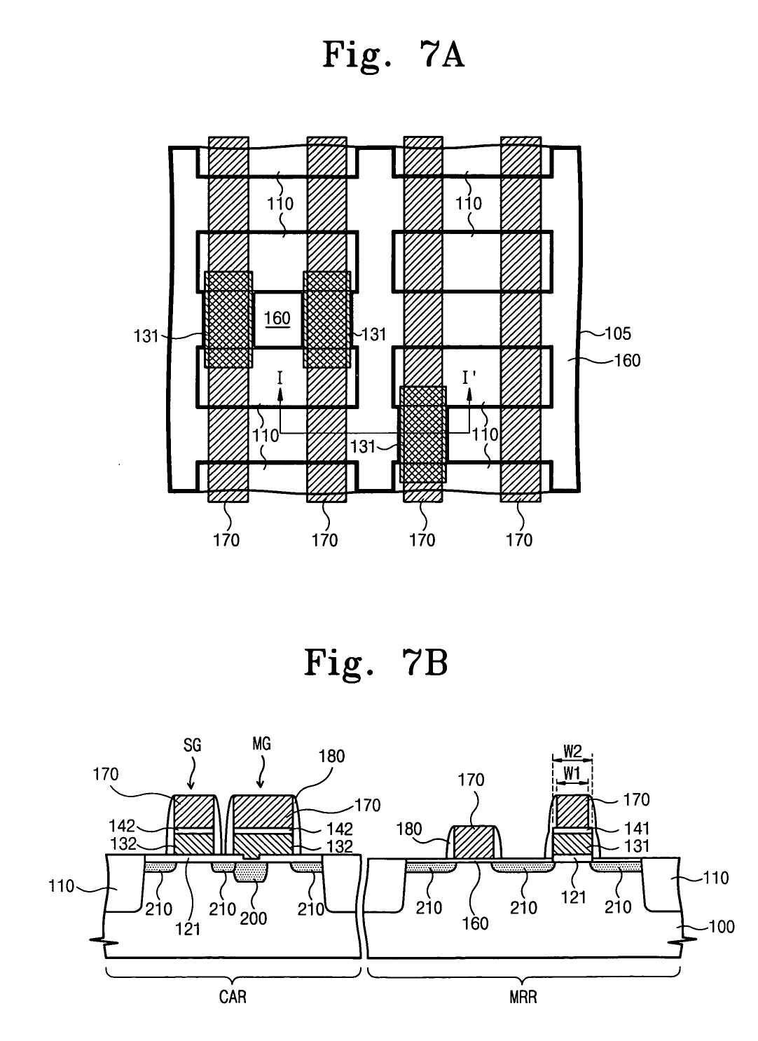

Thereafter, referring to FIGS. 7A and 7B, a second conductive layer is deposited on the resultant structure including the second gate insulating layer 160. The second conductive layer may be formed of, for example, a conductive material containing polycrystalline silicon. The second conductive layer may be formed of, for example, a sequentially stacked polycrystalline silicon and silicide layer. The second conductive layer may be deposited to a thickness of about 600 Å through about 3000 Å.

A gate patterning process is carried out to gate lines 170 on the active region 105. This gate patterning process may be divisionally conducted with steps of forming a nonvolatile gate structure in the floating-gate nonvolatile memory area and forming a MOS gate electrode in the rest area.

The forming of the nonvolatile gate structure is carried out including a step of sequentially etching the second conductive layer, the first inter-gate dielectric pattern 141, and the first floating conductive pattern 131. The second conductive layer and the first inter-gate dielectric pattern 141 are stacked on the first floating conductive pattern 131. This step is preferred to proceed, until exposing the first gate insulation pattern 121, by using a single etching mask. As a result, in the cell array region CAR of the nonvolatile memory area, memory and selection gate patterns MG and SG are formed with each including a second floating conductive pattern 132, a second inter-gate dielectric pattern 142, and a gate line 170. The memory gate pattern MG is arranged on the tunnel insulating layer 125, crossing over the isolation patterns 110. Here, the second floating conductive pattern 132 of the memory gate pattern MG is isolated from the gate line 170 through the second inter-gate dielectric pattern 142, being used for a floating gate electrode. On the other side, the second floating conductive pattern 132 of the selection gate pattern SG is electrically coupled to the gate line 170 at a predetermined region.

Forming the MOS gate electrode is carried out including a step of anisotropically etching the second conductive layer until exposing the second gate insulating layer 160 and the first inter-gate dielectric pattern 141. The gate line 170 is patterned to intersect the active regions 105 on the second gate insulating layer 160. These gate lines 170 are used for gate electrodes of transistors constituting the mask ROM and logic circuits in the EML semiconductor device.

The gate line 170 is disposed even over the first floating conductive pattern 131 in the mask ROM region MRR, being isolated from the first floating conductive pattern 131 through the first inter-gate dielectric pattern 141. Moreover, to reduce defects according to misalignment, a width W1 of the gate line 170 placed on the first floating conductive pattern 131, as shown in FIG. 7B, is preferred to be less than or equal to (not greater than) a width W2 of the first floating conductive pattern 131, e.g., W1≦W2.

After the gate patterning process, an ion implantation process is carried out using the gate lines 170 as a mask, thereby forming impurity regions 210 in the active region 105. The impurity regions 210 are used for source and drain electrodes of transistors constituting the EML semiconductor device. During this, the impurity regions 210, which are disposed in the mask ROM region MRR and the cell array region CAR of the floating-gate nonvolatile memory, may be formed in different ion implantation steps from each other, and also be dissimilar to each other. According to an embodiment of the invention, the impurity regions 210 are configured to be similar to the structure of source/drain electrodes for a low-voltage transistor. For instance, the impurity regions 210 disposed in the mask ROM region MRR may be constructed in the structure of typical lightly-doped drain (LDD) or LDD with halo region. Forming the impurity regions 210 may be carried out including a step of forming gate spacers 180 used for the ion implantation mask.

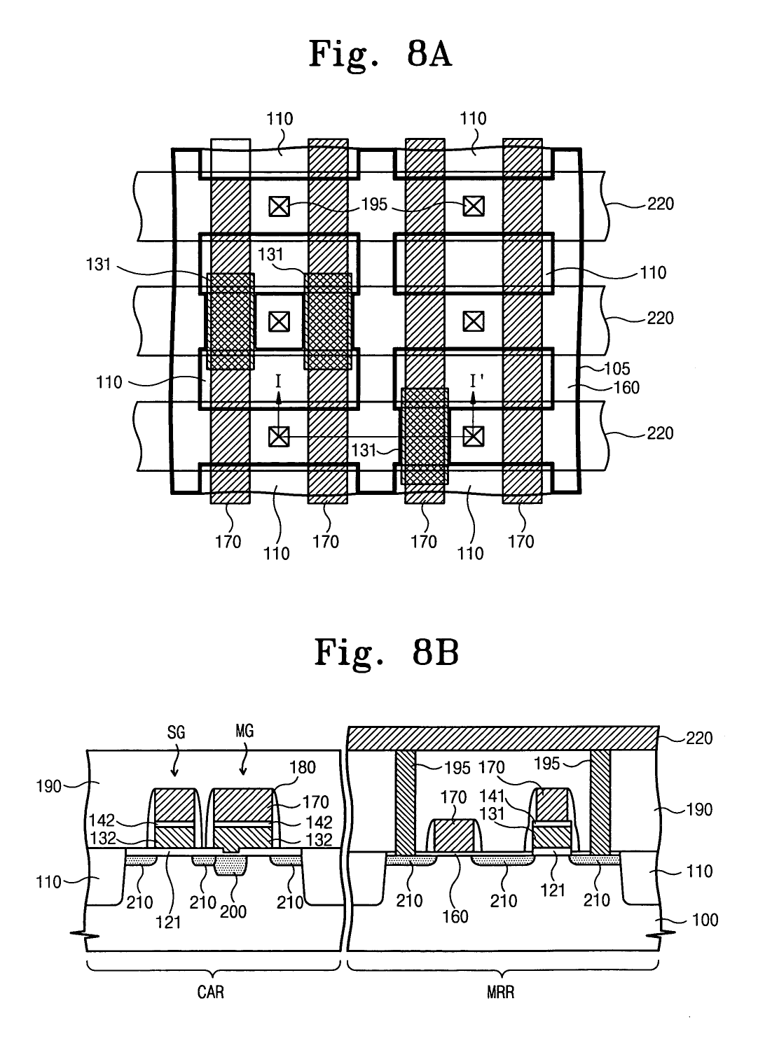

Next, referring to FIGS. 8A and 8B, an interlevel dielectric 190 is deposited on the resultant structure including the impurity regions 210. The interlevel dielectric 190 may be made of, for example, silicon oxide formed by means of CVD, Then, after patterning the interlevel dielectric 190 to form contact holes that expose the impurity regions 210, contact plugs 195 are formed to fill the contact holes. On the interlevel dielectric 190, bit lines 220 are arranged to contact the contact plugs 195, intersecting the gate lines 170.

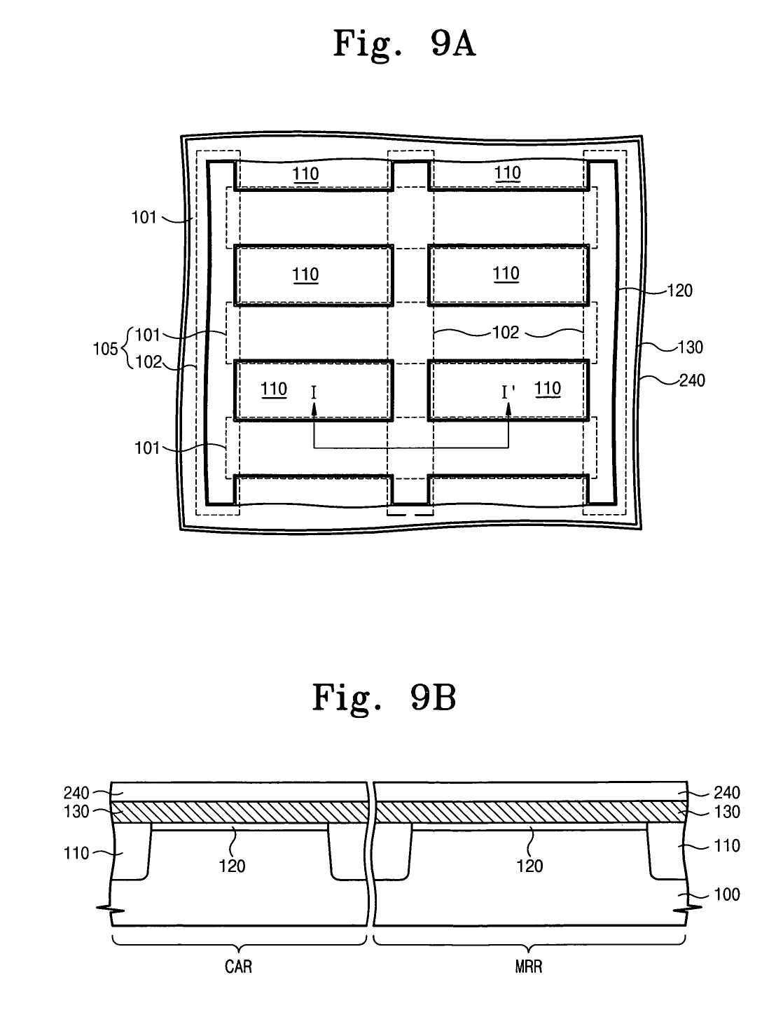

FIGS. 9A through 13A are plane diagrams illustrating a method of fabricating a mask ROM in accordance with an embodiment of the invention. Also, FIGS. 9B through 13B are sectional diagrams illustrating a method of fabricating a mask ROM, accompanying with FIGS. 9A through 13A. In FIGS. 9B through 13B, the cell array region CAR depicted at the left side shows a section of cell array in the split-gate nonvolatile memory, while the mask ROM region MRR depicted at the right side is correspondent with a section taken along line I-I′ of FIGS. 9A through 13B.

In this embodiment, as the kind of the nonvolatile memory accompanying with the mask ROM in a EML semiconductor device is a split-gate flash memory, it is different from the formed feature of fabricating the EML semiconductor device equipped with the floating-gate nonvolatile memory (e.g, FLOTOX EEPROM), illustrated by FIGS. 4B through 8B, in processing steps. But, except for that difference, the features of the present embodiment are substantially similar to those shown in FIGS. 4B through 8B. Accordingly, a description of the features described in FIGS. 4B through 8B which are the same as features in the present exemplary embodiment will not be repeated hereinafter.

First, referring to FIGS. 9A and 9B, after depositing the first gate insulating layer 120 on the active region 105, the first conductive layer 130 and a mask layer 240 are sequentially deposited on the resultant structure including the first gate insulating layer 120. Different from the aforementioned embodiment, the present embodiment excludes the steps of forming the tunnel insulating layer 125 and the tunnel impurity region 200. Thus, the first gate insulating layer 120 is formed to a uniform thickness between the first conductive layer 130 and the active region 105. The mask layer 240 may be formed of, for example, silicon nitride or silicon oxynitride by means of CVD.

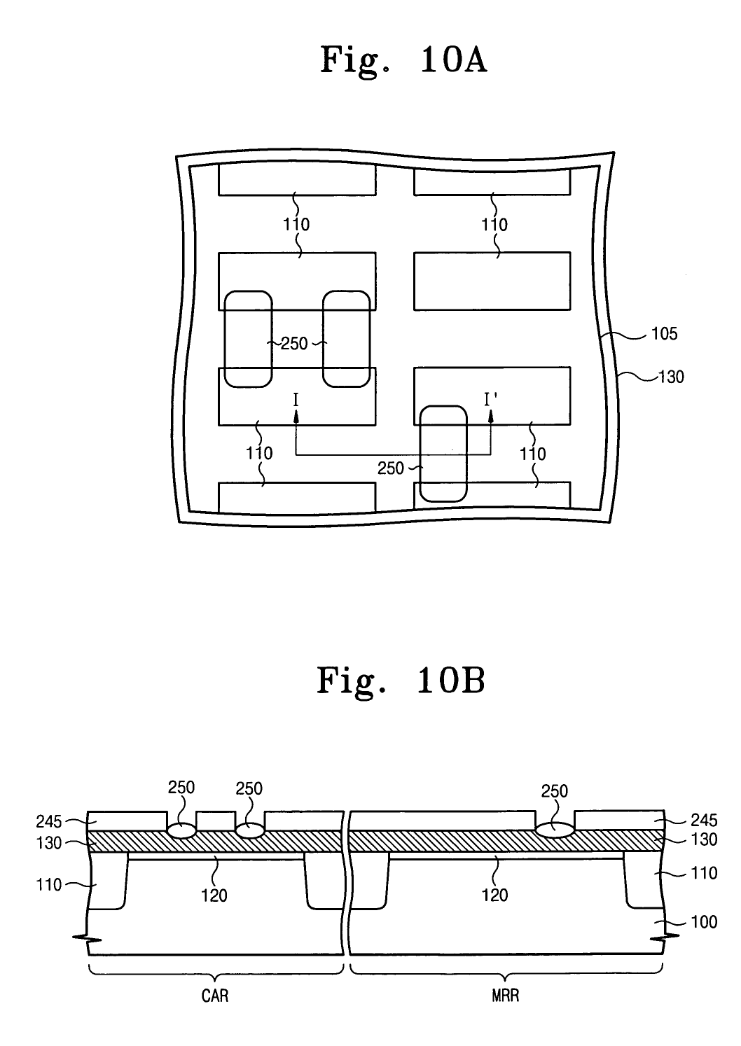

Next, referring to FIGS. 10A and 10B, the mask layer 240 is patterned to form a mask pattern 245 having openings that partially expose the top of the first conductive layer 130. Thereafter, the first conductive layer 130 exposed is thermally oxidized to form a silicon oxide pattern 250 on the bottoms of the openings. This thermal oxidation may be carried out in a manner similar to the well-known local oxidation of silicon (LOCOS) process. As a result, the silicon oxide pattern 250 is formed having a sectional shape of a thick convex lens at the center rather than the edge.

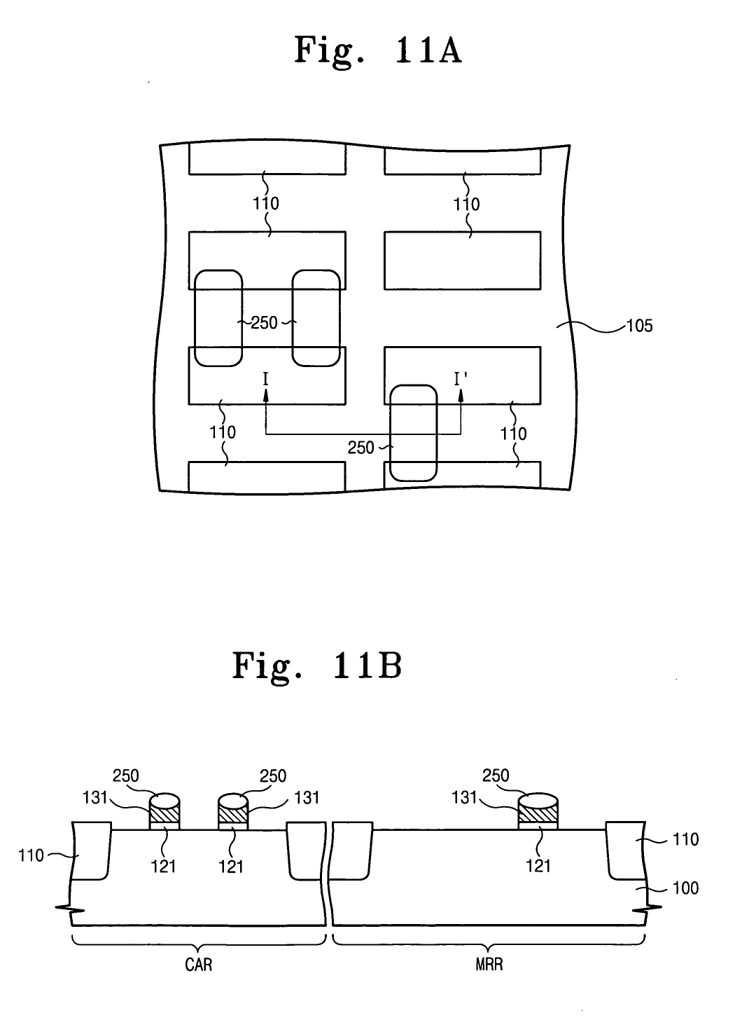

Next, referring to FIGS. 11A and 11B, the mask pattern 245 is removed to expose the first conductive layer 130. This step may be carried out using a wet etching process by using an etch recipe with etching selectivity to the silicon oxide pattern 250. Using the silicon oxide pattern 250 for an etching mask, the first conductive layer 130 and the first gate insulating layer 120, which are being exposed, are patterned. As a result, under the silicon oxide pattern 250, the first gate insulation pattern 121 and the first floating conductive pattern 131, being stacked in sequence are formed exposing the top of the active region 105.

Meanwhile, as aforementioned, as the silicon oxide pattern 250 has convex type shape, the first floating conductive pattern 131 thereunder is configured having the shape of concave lens where the edge is thicker than the center. In other words, an edge section of the first floating conductive pattern 131 is configured in an acute angle. If the conductive pattern is shaped with an acute angle, an electric field may be concentrated on the sharp portion thereof. The split-gate flash memory is operable using such an effect of electric field concentration to enhance the efficiency of a writing operation.

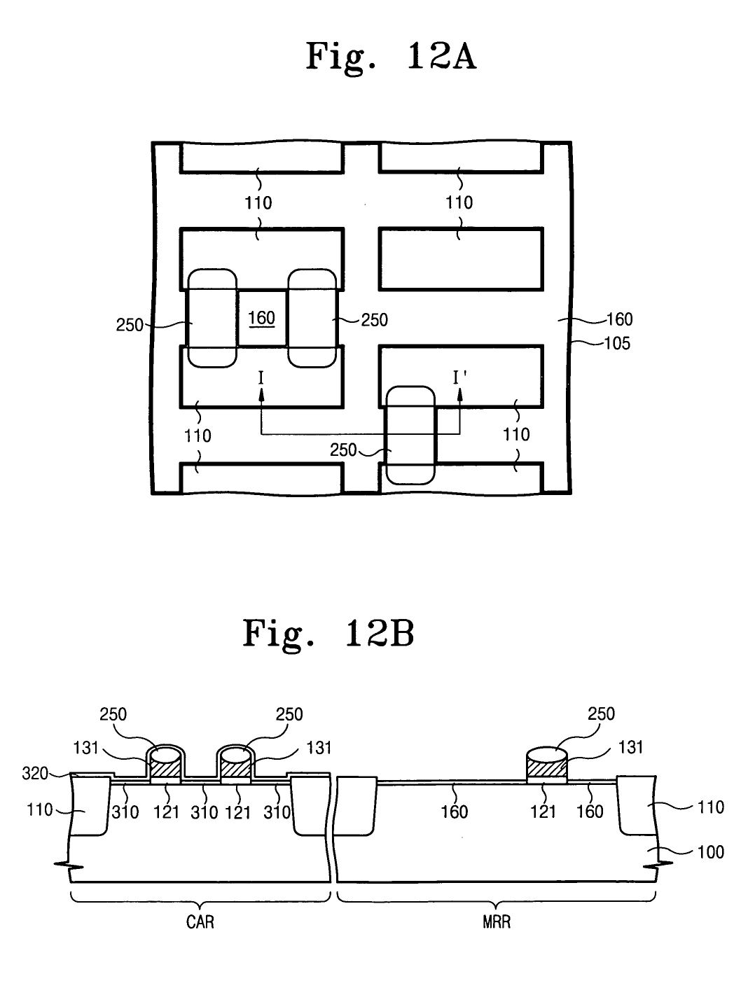

Next, referring to FIGS. 12A and 12B, the second gate insulating layer 160 is deposited on the active region around the first floating conductive pattern 131. According to this embodiment, the second gate insulating layer 160 is formed thinner than the first gate insulation pattern 121 in the exposed active region 105 of the mask ROM region MRR.

Meanwhile, before depositing the second gate insulating layer 160, a step of forming a tunnel insulating layer 310 and an inter-gate dielectric layer 320 in the active region 105 of the split-gate nonvolatile memory area may be conducted. The tunnel insulating layer 310 may be formed by, for example, thermally oxidizing the top of the exposed active region 105. The inter-gate dielectric layer 320 may be formed, for example, by means of CVD, all over the resultant structure including the tunnel insulating layer 310. According to this embodiment, the inter-gate dielectric layer 320 may be, for example, a medium-temperature oxide (MTO) layer formed by CVD. Thus, the tunnel insulating layer 310 may be formed on a sidewall of the floating conductive pattern 131, while the tunnel insulating layer 310 and the inter-gate dielectric layer 320 may be formed in the mask ROM region MRR.

In addition, before depositing the second gate insulating layer 160, a step of removing the tunnel insulating layer 310 and the inter-gate dielectric layer 320 from predetermined areas including the mask ROM region MRR is conducted. The removal operation is may be carried out by using, for example, an etching mask with a photoresist pattern covering the spit-gate nonvolatile memory area. The second gate insulating layer 160 is formed by means of thermal oxidation after the removal operation.

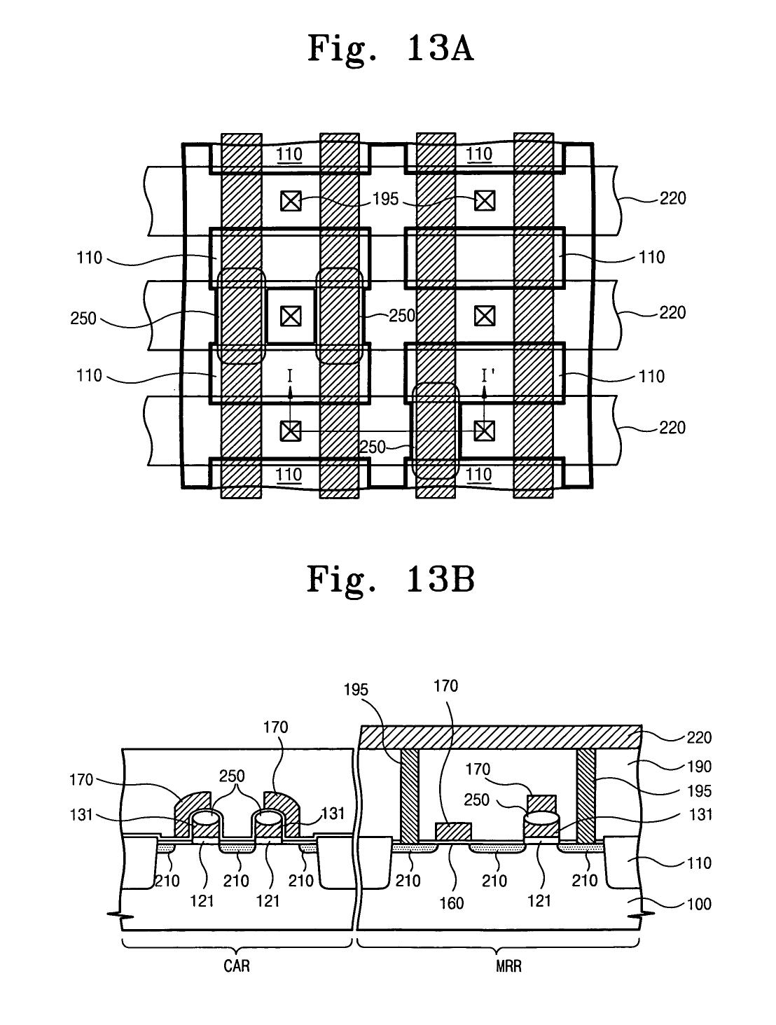

Then, referring to FIGS. 13A and 13B, after depositing the second conductive layer on the resultant structure including the second gate insulating layer 160, the second conductive layer is patterned to form the gate lines 170. Forming the gate lines 170 is carried out including a step of anisotropically etching the second conductive layer until exposing the second gate insulating layer 160 and the first inter-gate dielectric pattern 141. The gate line 170 is disposed on the second gate insulating layer 160 and patterned to intersect the active region 105. These gate lines 170 are used for gate electrodes of transistors constituting the mask ROM and logic circuits, and control gate electrodes of the split-gate nonvolatile memory transistors.

As with the aforementioned embodiment, the width W1 of the gate line 170 placed on the first floating conductive pattern 131 is preferred to be less than or equal to the width W2 of the first floating conductive pattern 131, e.g., W1≦W2. After forming the gate lines 170, in the same way as performed in the previous embodiment, the impurity regions 210, the interlevel dielectric 190, the contact plugs 195, and the bit lines 220 are formed.

The mask ROM device according to the present embodiment of the invention is comprised of the off-transistors. The off-transistor has a structure similar to that of the floating-gate or split-gate nonvolatile memory cell transistor. Hereinafter, a mask ROM structure of an embodiment of the invention will be described with reference to FIGS. 8A and 8B or 13A and 13B. But, as certain aspects of the mask ROM structure of an embodiment of the invention have already been explained through the description about the fabrication method thereof, only those structural features not previously described will be discussed in further detail hereinafter. Furthermore, the mask ROM structure of the present embodiment of the invention is not limited to the following description.

Returning to FIGS. 8A and 8B, the mask ROM device is comprised of the isolation patterns 110 that are located in the predetermined regions of the semiconductor substrate 100 and confine the active regions 105 therein. The active region 105 includes the first active regions 101 extending in one direction, and the second active regions 102 extending in the other direction to connect the first active regions 101 to each other. The first active regions 101 are used for drain and channel regions of the transistors, while the second active regions 102 are used for source regions of the transistors. According to embodiments of the present invention, the isolation patterns 110 may be configured having the shape of islands on a longitudinal axis parallel with the first active regions 101 and the active region 105 may be formed having the shape of a net enclosing the isolation patterns 110.

The gate lines 170 used as word lines are disposed over the active regions 105. Between the gate lines 170 and the active regions 105 are interposed the gate insulating layers. According to an embodiment, the gate insulating layer can be divided into the first gate insulation pattern 121 and the second gate insulating layer 160 in accordance with thickness. The first gate insulation pattern 121 is used for a gate insulating layer of the off-transistor disposed at the off-cell region, while the second insulating layer 160 is used for a gate insulating layer of the on-transistor disposed at the on-cell region. Also, the first gate insulation pattern 121 may be thicker than the second gate insulating layer 160. For instance, the first gate insulation pattern 121 may be formed to a thickness of about 50 Å through about 400 Å, while the second gate insulating layer 160 may be formed to a thickness of about 10 Å through about 50 Å.

From this difference of thickness therebetween, under a predetermined condition of read voltage, the channel region under the first gate insulation pattern 121 may not be turned on even when the channel region under the second gate insulating layer 160 becomes conductive. Therefore, the mask ROM according to embodiments of the invention is able to utilize a threshold voltage difference along the difference of thickness on the gate insulating layer in differentiating information stored at the cell transistor.

The mask ROM of embodiments of the invention may be a part of the EML semiconductor device comprising the floating-gate nonvolatile memory. In this case, the first gate insulation pattern 121 may be used as a gate insulating layer of the floating-gate nonvolatile memory.

In addition, according to embodiments of the invention, the first floating conductive pattern 131 may be disposed between the gate insulating layer of the off-transistor and the gate line 170. The first floating conductive pattern 131 may be isolated from the conductive structure including the gate line 170. For this electrical isolation, the first inter-gate dielectric pattern 141 may be interposed between the first floating conductive pattern 131 and the gate line 170.

Such an electrical isolation of the first floating conductive pattern 131 is beneficial for reducing a voltage of the gate line 170 that is applied to the active region 105, thereby contributing to establishing the threshold voltage difference between the on and off-transistors. As a result, the mask ROM of the embodiments of the invention is able to utilize the threshold voltage difference, according to presence or absence of the first floating conductive pattern 131 in sensing information stored therein.

The first floating conductive pattern 131 may be formed of, for example, a conductive material including polycrystalline silicon. The first floating conductive pattern 131 may be formed of, for example, a sequentially stacked polycrystalline silicon and silicide layer. Here, the thickness of the gate line 170 may be about 600 Å through about 3000 Å, while the thickness of the first inter-gate dielectric pattern 141 may be about 80 Å through about 200 Å.

Meanwhile, in the nonvolatile memory area, the second floating conductive pattern 132 and the second inter-gate dielectric pattern 142 may be formed with the same materials and thicknesses as the first floating conductive pattern 131 and the first inter-gate dielectric pattern 142 (here, ‘identity’ of material and thickness means a resultant material formed by the same processing manner, by which they are identical to each other in the range of processing error generating from the fabrication procedure). The second floating conductive pattern 132 is used as a floating gate electrode, while the gate line 170 is placed on the second inter-gate dielectric pattern 142 and used as a control gate electrode.

The impurity regions 210 are formed in the active region 105 at both gates of the gate line 170. According to an embodiment of the invention, over the first active region 101, a couple of the gate lines 170 are arranged in parallel with the second active region 102. Here, the impurity region 210 located at the first active region 101 between the couple of the gate lines 170 is used for a drain region of the mask ROM cell transistor, while the impurity region 210 located at the second active region 102 is used for a source region of the mask ROM cell transistor. As aforementioned and illustrated in FIG. 8A, as the first active regions 101 are connected to each other through the second active regions 102, the impurity regions 210 located in the second active region 102 are used as a common source region.

The interlevel dielectric 190 is placed over the gate lines 170. The contact plugs 195 are connected to the impurity regions 210, penetrating the interlevel dielectric 190. In addition, along the direction intersecting the gate lines 170, the bit lines 220 are disposed on the interlevel dielectric 190 to connect the contact plugs 195 to each other.

According to another embodiment, the gate of the off-transistor employed in the mask ROM device may be constructed similar to the gate of the split-gate flash memory device. In further detail, returning to FIGS. 13A and 13B, between the first floating conductive pattern 131 and the gate line 170 may be interposed the silicon oxide pattern 250 to electrically isolate the gate line 170 and the first floating conductive pattern from each other. Thus, as with the aforementioned embodiment, the first floating conductive pattern 131 is electrically isolated to down a voltage of the gate line 170 that is applied to the active region 105.

In this structure, the configuration that the first floating conductive pattern 131 is disposed only in the off-transistor but not the on-transistor is also applied to the silicon oxide pattern 250. Consequently, the mask ROM of the present embodiment of the invention is able to utilize the threshold voltage difference, according to presence or absence of the first floating conductive pattern 131 and the silicon oxide pattern 250 in sensing information stored therein.

According to the embodiments of the invention, the floating conductive patterns insulated from the gate lines are selectively disposed at the gates of the off-transistors. Namely, there is no floating conductive pattern at the gates of the on-transistors. The presence or absence of the floating conductive pattern causes a difference of effects with the gate line voltage applied to the channel region, which is available to generate a threshold voltage difference between the on and off-transistors. As a result, the mask ROM according to embodiments of the invention, in comparison to the conventional art, which, as discussed, may require additional photolithography and high-energy ion implantation processes, is able to be fabricated at a lower cost than the conventional processes. In addition, as a result, the mask ROM of embodiments of the invention are free from a short channel effect that is caused by conventional high-energy ion implantation processes.

Additionally, according to embodiments of the invention, the off-transistor has a thicker gate insulating layer than the on-transistor. This difference of thickness in the gate insulating layers also generates a threshold voltage difference between the on and off-transistors, which may in turn be used in differentiating information recorded in the mask ROM.

Moreover, with the embodiments of the invention, one has the ability to control the presence/absence of the floating conductive pattern and the thickness difference by means of the fabrication processes for the nonvolatile memory. As a result, the EML semiconductor device according to the embodiments of the invention can be comprised of a mask ROM with advanced characteristics without increasing the number of processing steps.

Having described the exemplary embodiments of the present invention, it is further noted that it is readily apparent to those of reasonable skill in the art that various modifications may be made without departing from the spirit and scope of the invention which is defined by the metes and bounds of the appended claims.

What is claimed is:

1. A mask read only memory (ROM) device comprising:
a plurality of isolation patterns disposed at predetermined regions of a semiconductor substrate to define a plurality of active regions, the semiconductor substrate comprising a mask ROM region where a plurality of on cells and a plurality of off-cells are disposed;
a plurality of gate lines disposed over the active regions and which cross over the isolation patterns;
a plurality of gate insulating layers interposed between the gate lines and the active regions; and
a floating conductive pattern and an inter-gate dielectric pattern located between the gate line and the gate insulating layer of the off-cell.

2. The mask ROM device of claim 1, wherein the gate insulating layer is thicker under the gate line of the off-cell than under the gate line of the on-cell.

3. The mask ROM device of claim 2, wherein the gate insulating layer is formed to a thickness of about 10 Å through about 50 Å under the gate line of the on-cell and is formed in a thickness of about 50 Å through about 400 Å under the gate line of the off-cell.

4. The mask ROM device of claim 1, wherein the floating conductive pattern is electrically isolated from the gate line by the inter-gate dielectric pattern.

5. The mask ROM device of claim 1, wherein the inter-gate dielectric pattern is formed of at least one high-k dielectric layer material selected from the group consisting of metallic oxides, a silicon oxide layer, and a silicon nitride layer.

6. The mask ROM device of claim 1, wherein in the off-cell, the gate line is not greater than the floating conductive pattern in width.

7. A semiconductor device having a mask read only memory (ROM) comprising:
a plurality of isolation patterns disposed at predetermined regions of a semiconductor substrate to define a plurality of active regions, the semiconductor substrate comprising a nonvolatile memory area and a mask ROM region where a plurality of on cells and a plurality of off-cells are disposed;
a plurality of gate lines disposed over the active regions and which cross over the isolation patterns;
a plurality of gate insulating layers interposed between the gate lines and the active regions;
a first floating conductive pattern and a first inter-gate dielectric pattern located between the gate line and gate insulating layer of the off-cell; and
a second floating conductive pattern and a second inter-gate dielectric pattern located between the gate line and gate insulating layer of the nonvolatile memory area,
wherein in the on-cell, the gate line directly contacts the gate insulating layer.

8. The semiconductor device of claim 7, wherein the gate insulating layer is thicker under the gate line of the off-cell than under the gate line of the on-cell.

9. The semiconductor device of claim 8, wherein the gate insulating layer under the gate line of the off-cell includes a part having the same thickness as the gate insulating layer under the gate line of the nonvolatile memory area.

10. The semiconductor device of claim 9, wherein the gate insulating layer is formed to a thickness of about 10 Å through about 50 Å under the gate line of the on-cell and is formed to a thickness of about 50 Å through about 400 Å under the gate lines of the off-cell and the nonvolatile memory area.

11. The semiconductor device of claim 7, wherein the first floating conductive pattern is the same as the second floating conductive pattern with regard to kind of material and to thickness.

12. The semiconductor device of claim 7, wherein the first inter-gate dielectric pattern is the same as the second inter-gate dielectric pattern with regard to kind of material and to a thickness.

13. The semiconductor device of claim 7, wherein the first and second floating conductive patterns are electrically isolated from the gate lines by the first and second inter-gate dielectric patterns.

14. The semiconductor device of claim 7, wherein at least one of the first and second inter-gate dielectric patterns is formed of at least one high-k dielectric layer material selected from the group consisting of metallic oxides, a silicon oxide layer, and a silicon nitride layer.

15. The semiconductor device of claim 7, wherein the gate line of the off-cell is no greater than the first floating conductive pattern in width and the gate line of the nonvolatile memory area is equal to the second floating conductive pattern in width.

16. The semiconductor device of claim 7, wherein the gate insulating layer of the nonvolatile memory area comprises a tunnel region,
wherein the gate insulating layer of the tunnel region is thinner than the adjacent region.

17. The semiconductor device of claim 7, further comprising:
a plurality of silicon oxide patterns disposed between the first floating conductive pattern and the first inter-gate dielectric pattern and between the second floating conductive pattern and the second inter-gate dielectric pattern to define top edges of the first and second floating conductive patterns in acute angles.

18. A mask read only memory (ROM) device comprising:
a semiconductor substrate including a mask ROM cell array including a plurality of on-transistors and a plurality of off-transistors;
a plurality of first active regions disposed in predetermined areas of the semiconductor substrate along one direction, the first active regions being used as drain and channel regions of the on and off-transistors;
a plurality of second active regions disposed in predetermined areas of the semiconductor substrate along the other direction to connect the first active regions with each other, the second active regions being used as source regions of the on and off-transistors,
a plurality of gate lines crossing over the first active regions to serve as gate lines for the on and off-transistors;
a plurality of bit lines crossing over the gate lines to connect the drain regions with each other; and
a floating conductive pattern and an inter-gate dielectric pattern disposed between the gate line of the off-transistor and the first active region.

19. The mask ROM device of claim 18, further comprising:
a plurality of gate insulating layers disposed between the first active regions and the gate lines,
wherein the gate insulating layer disposed under the gate line of the off-transistor is interposed between the floating conductive pattern and the first active region.

20. The mask ROM device of claim 19, wherein the gate insulating layer is thicker under the gate line of the off-transistor than under the gate line of the on-transistor.

21. A method of fabricating a mask read only memory (ROM) device, comprising:
forming a plurality of isolation patterns in a semiconductor substrate to define a plurality of active regions, the semiconductor substrate comprising a mask ROM region where a plurality of on cells and a plurality of off-cells are disposed;
forming a first gate insulation pattern and a floating conductive pattern on the active region of the off-cell to expose the active region of the on-cell;
forming a second gate insulating layer on the exposed active region of the on-cell; and
forming a plurality of gate lines over the second gate insulating layer of the on-cell and the first floating conductive pattern of the off-cell.

22. The method of claim 21, wherein the second gate insulating layer is formed to be thinner than the first gate insulation pattern.

23. The method of claim 22, wherein the first gate insulation pattern is formed to a thickness of about 50 Å through about 400 Å, and the second gate insulating layer is formed in a thickness of about 10 Å through about 50 Å.

24. The method of claim 21, wherein the forming of the first gate insulation and floating conductive patterns comprises:
forming a first gate insulating layer on the active region;
forming a first conductive layer on the resultant structure including the first gate insulating layer; and
patterning the first conductive layer and the gate insulating layer to expose the top of the active region of the on-cell.

25. The method of claim 24, further comprising: forming an inter-gate dielectric layer on the first conductive layer after forming the first conductive layer,
wherein the inter-gate dielectric layer is patterned during the step of patterning of the first conductive layer and the gate insulating layer, to form an inter-gate dielectric pattern disposed between the first floating conductive pattern and the gate line.

26. The method of claim 24, further comprising: forming a silicon oxide pattern on a predetermined region of the first conductive layer after forming the first conductive layer,
wherein the silicon oxide pattern is used as an etching mask for defining the first floating conductive pattern and the gate insulation pattern in the step of patterning the first conductive and gate insulating layers.

27. The method of claim 26, further comprising:
forming a tunnel insulating layer to cover the active region around the first floating conductive pattern, before forming the second gate insulating layer;
forming an inter-gate dielectric layer to cover the resultant structure including the tunnel insulating layer; and
removing the inter-gate dielectric layer and the tunnel insulating layer from the mask ROM region.

28. The method of claim 21, wherein the gate line is not greater than the first floating conductive pattern in width.

29. A method of fabricating a semiconductor device, comprising:
forming a plurality of isolation patterns in a semiconductor substrate to define a plurality of active regions, the semiconductor substrate comprising a nonvolatile memory area and a mask read only memory (ROM) region where a plurality of on-cells and a plurality of off-cells are disposed;
forming a first gate insulation pattern and a floating conductive pattern on the nonvolatile memory area and the active region of the off-cell;
forming a second gate insulating layer on the active region around the first floating conductive pattern; and
forming a plurality of gate lines on the second gate insulating layer of the on-cell, the first floating conductive pattern of the off-cell and the nonvolatile memory area, the gate lines crossing over the active regions.

30. The method of claim 29, wherein the second gate insulating layer is thinner than the first gate insulation pattern.

31. The method of claim 30, wherein the first gate insulation pattern is formed to a thickness of about 50 Å through about 400 Å, while the second gate insulating layer is formed to a thickness of about 10 Å through about 50 Å.

32. The method of claim 29, wherein forming the first gate insulation and floating conductive patterns comprises:
forming a first gate insulating layer on the active region;
forming a first conductive layer on the resultant structure including the first gate insulating layer; and
patterning the first conductive and gate insulating layers to expose the top of the active region of the on-cell.

33. The method of claim 32, further comprising: forming an inter-gate dielectric layer on the first conductive layer after forming the first conductive layer,
wherein the inter-gate dielectric layer is patterned during the step of patterning of the first conductive layer and the gate insulating layer to form an inter-gate dielectric pattern disposed between the first floating conductive pattern and the gate line.

34. The method of claim 32, further comprising: forming a silicon oxide pattern on a predetermined region of the first conductive layer after forming the first conductive layer,
wherein the silicon oxide pattern is used as an etching mask for defining the first floating conductive pattern and the gate insulation pattern in the step of patterning the first conductive and gate insulating layers.

35. The method of claim 34, further comprising:
forming a tunnel insulating layer to cover the active region around the first floating conductive pattern before forming the second gate insulating layer;
forming an inter-gate dielectric layer to cover the resultant structure including the tunnel insulating layer; and
removing the inter-gate dielectric layer and the tunnel insulating layer from the mask ROM region.

36. The method of claim 29, wherein in the off-cell, the gate line is not greater than the first floating conductive pattern in width.

37. A method of fabricating a mask read only memory (ROM) device, comprising:
forming a plurality of isolation layers in predetermined regions of a semiconductor substrate including a plurality of on cells and a plurality of off-cells to define a plurality of first active regions and a plurality of second active regions, the first active regions being disposed along one direction and the second active regions being disposed along the other direction to connect the first active regions with each other;
forming a first gate insulation pattern and a floating conductive pattern on the active region of the off-cell;
forming a second gate insulating layer on the first and second active regions around the first floating conductive pattern;
forming a gate line crossing over the first active regions and disposed over the second gate insulating layer of the on-cell and the first floating conductive pattern of the off-cell; and
forming drain and source regions in the first and second active regions by using the gate lines as an ion implantation mask.

38. The method of claim 37, wherein the second gate insulating layer is thinner than the first gate insulation pattern.

39. The method of claim 37, wherein the first and second active regions are formed to intersect each other,
wherein the isolation patterns are formed being enclosed by the first and second active regions,
wherein the isolation patterns have a longitudinal axis parallel with the first active regions.

40. The method of claim 39, wherein a couple of the gate lines are formed on each of the isolation patterns,
wherein the couple of the gate lines are arranged in parallel with the first active regions.
